(19) United States
(12) Patent Application Publication
(10) Pub. No.: US 2026/0161091 A1
(43) Pub. Date: Jun. 11, 2026

(54) METHOD FOR MANUFACTURING SEMICONDUCTOR DEVICE

(71) Applicant: Resonac Corporation, Minato-ku, Tokyo (JP)

(72) Inventors: Yuki MIYAMOTO, Minato-ku, Tokyo (JP); Chikashi AOYAGI, Minato-ku, Tokyo (JP); Yoshikatsu TOUBARU, Minato-ku, Tokyo (JP); Masayuki WADA, Minato-ku, Tokyo (JP); Keiichi SAKAMOTO, Minato-ku, Tokyo (JP); Shigeru YAMAKI, Minato-ku, Tokyo (JP); Tatsuya MAKINO, Minato-ku, Tokyo (JP); Hidekazu KONDO, Minato-ku, Tokyo (JP)

(21) Appl. No.: 18/861,270

(22) PCT Filed: Mar. 28, 2024
(86) PCT No.: PCT/JP2024/012830

§ 371 Date: Oct. 29, 2024

(30) Foreign Application Priority Data
Mar. 31, 2023 (JP) 2023-058055

(51) Int. Cl. G03F 7/32; G03F 7/42; H10P 58/00; H10W 80/00

(52) U.S. Cl. CPC G03F 7/322; G03F 7/425; H10P 58/20; H10W 80/301

(57) ABSTRACT

A manufacturing method of a semiconductor device, the manufacturing method containing: a step of forming a photosensitive resin layer on one main surface of a semiconductor wafer; a step of forming an opening through which the semiconductor wafer is exposed by removing a part of the photosensitive resin layer by light irradiation and development using a developing solution; a step of dividing the semiconductor wafer along the opening by plasma dicing to form a semiconductor chip having a first main surface and a second main surface on a side opposite thereto and provided with the photosensitive resin layer on the first main surface; a step of removing the photosensitive resin layer on the semiconductor chip; and a step of hybrid bonding the semiconductor chip and another semiconductor member such that the first main surface of the semiconductor chip is in contact with the semiconductor member.

### TECHNICAL FIELD

The present disclosure relates to a manufacturing method of a semiconductor device.

### BACKGROUND ART

In the manufacturing process of a semiconductor device, there is a case where a semiconductor wafer is individually divided into semiconductor chips by plasma dicing. In the plasma dicing, for example, after a mask partially covering a semiconductor wafer is formed on a semiconductor wafer, a portion of the semiconductor wafer not covered with the mask is selectively etched by plasma irradiation from the top of this mask, thereby dividing the semiconductor wafer.

As a method of forming the mask as described above, a method is mentioned in which a layer covering the entire surface of a semiconductor wafer is formed, and then a part of this layer is removed by laser processing. However, in the laser processing, debris (processing dust) was sometimes scattered around the processing part and adhered to the semiconductor chip to be produced. In the case of using the semiconductor chip with adhered debris in a semiconductor device, a decrease in reliability or the like may occur. Therefore, a method of suppressing debris residues associated with laser processing in a semiconductor chip when a semiconductor chip is produced has been studied (for example, Patent Literature 1).

### CITATION LIST

### Patent Literature

Patent Literature 1: Japanese Unexamined Patent Publication No. 2019-50237

### SUMMARY OF INVENTION

### Technical Problem

As a bonding technique of a semiconductor chip and another semiconductor member (such as a semiconductor chip or a semiconductor wafer), hybrid bonding is mentioned. In the hybrid bonding, each of the semiconductor chip and the other semiconductor member have a bonding surface composed of an electrode and an insulating film, and these bonding surfaces are directly bonded to each other. Therefore, in the case of manufacturing a semiconductor device by utilizing hybrid bonding, when even a small amount of debris is adhered to the surface of the semiconductor chip, it may be particularly susceptible to the debris, and a problem may occur in connectivity or the like.

The present disclosure relates to a method capable of manufacturing a semiconductor device by plasma dicing while reducing the influence of debris or the like in hybrid bonding.

### Solution to Problem

An aspect of the present disclosure relates to a manufacturing method of a semiconductor device, the manufacturing method containing: a step of forming a photosensitive resin layer on one main surface of a semiconductor wafer; a step of forming an opening through which the semiconductor wafer is exposed by removing a part of the photosensitive resin layer by light irradiation and development using a developing solution; a step of dividing the semiconductor wafer along the opening by plasma dicing to form a semiconductor chip having a first main surface and a second main surface on a side opposite thereto and provided with the photosensitive resin layer on the first main surface; a step of removing the photosensitive resin layer on the semiconductor chip; and a step of hybrid bonding the semiconductor chip and another semiconductor member such that the first main surface of the semiconductor chip is in contact with the semiconductor member.

In the above-described manufacturing method, the photosensitive resin layer with an opening formed is used as a mask in plasma dicing. In the photosensitive resin layer, an opening can be formed not by laser processing, but by light irradiation and development using a developing solution. In this way, in the above-described manufacturing method, since it is not necessary to perform laser processing, which causes debris to be generated, in order to form a mask in plasma dicing, the influence of debris or the like in hybrid bonding can be reduced.

In the above-described manufacturing method, the developing solution may be a developing solution containing water. Furthermore, a pH of the developing solution may be 11 or less. In these cases, deterioration of components (such as a dicing tape and a dicing ring) used in the manufacturing of a semiconductor device can be suppressed.

In the above-described manufacturing method, the photosensitive resin layer may be a positive-type photosensitive resin layer. In a case where the photosensitive resin layer is a positive-type photosensitive resin layer, after plasma dicing, the photosensitive resin layer on the semiconductor chip can be easily removed by light irradiation and dissolution in a cleaning liquid.

The above-described manufacturing method may further contain a step of irradiating the photosensitive resin layer on the semiconductor chip with light. The photosensitive resin layer on the semiconductor chip may be removed by dissolution in a cleaning liquid. In this case, the cleaning liquid may be a cleaning liquid containing water. Furthermore, a pH of the cleaning liquid may be 11 or less.

In the above-described manufacturing method, the photosensitive resin layer may contain a reaction product of a polythiol compound having a disulfide bond and a cyclic ether compound having a polyether chain and two or more cyclic ether groups, and a photoradical generator.

### Advantageous Effects of Invention

According to an aspect of the present disclosure, there is provided a method capable of manufacturing a semiconductor device by plasma dicing while reducing the influence of debris or the like in hybrid bonding.

### BRIEF DESCRIPTION OF DRAWINGS

FIG. 1 is a schematic view illustrating an example of a manufacturing method of a semiconductor device.

FIG. 2 is a schematic view illustrating an example of a manufacturing method of a semiconductor device.

### DESCRIPTION OF EMBODIMENTS

The present invention is not limited by the following examples.

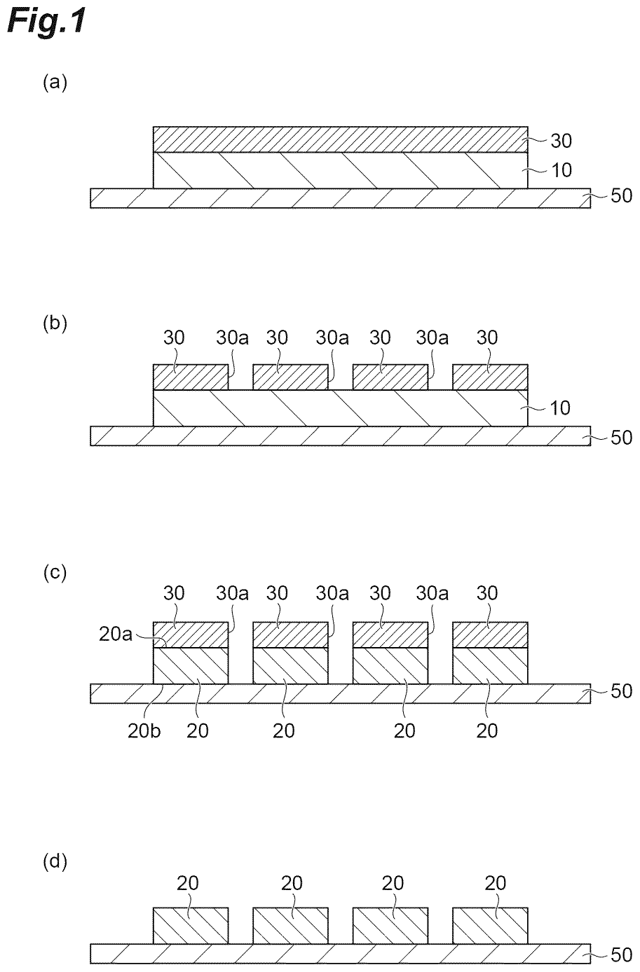

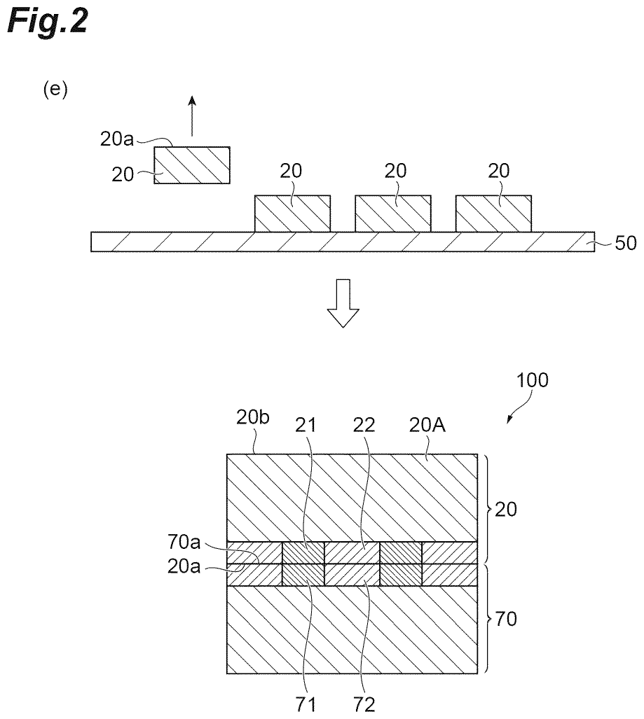

FIG. 1 and FIG. 2 are schematic views illustrating an example of a manufacturing method of a semiconductor device. The method illustrated in FIG. 1 and FIG. 2 contains: as illustrated in (a), a step of forming a photosensitive resin layer 30 on one main surface of a semiconductor wafer 10 (hereinafter, also referred to as “step (a)”); as illustrated in (b), a step of forming an opening 30a through which the semiconductor wafer 10 is exposed by removing a part of the photosensitive resin layer 30 by light irradiation and development using a developing solution (hereinafter, also referred to as “step (b)”); as illustrated in (c), a step of dividing the semiconductor wafer 10 along the opening 30a by plasma dicing to form a semiconductor chip 20 having a first main surface 20a and a second main surface 20b on a side opposite thereto and provided with the photosensitive resin layer 30 on the first main surface 20a (hereinafter, also referred to as “step (c)”); as illustrated in (d), a step of removing the photosensitive resin layer 30 on the semiconductor chip 20 (hereinafter, also referred to as “step (d)”); and as illustrated in (e), a step of hybrid bonding the semiconductor chip 20 and another semiconductor member 70 such that the first main surface 20a of the semiconductor chip 20 is in contact with the semiconductor member 70 (hereinafter, also referred to as “step (e)”).

In the step (a), the photosensitive resin layer 30 is formed on one main surface of the semiconductor wafer 10. The semiconductor wafer 10 may be, for example, a silicon wafer. An integrated circuit may be formed on one main surface side of the semiconductor wafer 10. The thickness of the semiconductor wafer 10 may be, for example, 10 μm or more and may be 1000 μm or less. Such a semiconductor wafer 10 can be produced, for example, by forming an integrated circuit on one main surface side of the semiconductor wafer 10 and then grinding the back surface of the surface on which the integrated circuit is formed.

An example of the semiconductor wafer 10 may be provided with a wafer main body part and an electrode and an insulating film provided on one main surface of the wafer main body part, and one main surface of the semiconductor wafer 10 on the photosensitive resin layer 30 side may be composed of an insulating film having an opening and an electrode provided in the opening of the insulating film. By dividing such a semiconductor wafer 10 in the step (c) described below, the semiconductor chip 20 having the first main surface 20a composed of an electrode and an insulating film can be formed. The electrode provided on the semiconductor wafer 10 may contain a through electrode penetrating the wafer main body part.

As illustrated in FIG. 1(a), the semiconductor wafer 10 may be fixed onto a dicing tape 50. A dicing ring may be attached to the dicing tape 50. Examples of the constituent material for the dicing tape 50 include an acrylic adhesive material, an unsaturated polyester adhesive material, a rubber-based adhesive material, and a urethane-based adhesive material. Furthermore, examples of the constituent material of the dicing ring include SUS, aluminum, an ABS resin, and a PSS resin.

The photosensitive resin layer 30 may be formed to cover the entire one main surface of the semiconductor wafer 10, and may be formed to cover a part thereof. The photosensitive resin layer 30 may be formed to cover the entire portion where an integrated circuit is formed in the semiconductor wafer 10. The photosensitive resin layer 30 may be a positive-type photosensitive resin layer, and may be a negative-type photosensitive resin layer. In a case where the photosensitive resin layer 30 is a positive-type photosensitive resin layer, in the step of removing the photosensitive resin layer on the semiconductor chip 20 described below, the photosensitive resin layer 30 on the semiconductor chip 20 can be easily removed by light irradiation and dissolution in a cleaning liquid.

In the step (b), a part of the photosensitive resin layer 30 is removed by light irradiation and development using a developing solution. Thereby, the opening 30a is formed in the photosensitive resin layer 30, and the semiconductor wafer 10 is exposed through the opening 30a. In a case where the photosensitive resin layer 30 is a positive-type photosensitive resin layer, a portion corresponding to the opening 30a of the photosensitive resin layer 30 is irradiated with light, and this portion is removed by dissolution in a developing solution.

A light source used for light irradiation may be, for example, an LED lamp, a mercury lamp (for example, a low-pressure mercury lamp, a medium-pressure mercury lamp, and a high-pressure mercury lamp), a metal halide lamp, an excimer lamp, or a xenon lamp. The light irradiation may be performed directly on the photosensitive resin layer 30, and may be performed through glass or the like. Examples of irradiated light include visible light and ultraviolet light. Light to be irradiated may be, for example, light containing light at a wavelength of 365 nm. The wavelength of light to be irradiated may be, for example, 150 to 550 nm.

The exposure dose of light irradiation may be, for example, 1000 mJ/cm² or more and may be 2000 mJ/cm² or less. In the present specification, the exposure dose means a product of illuminance (mW/cm²) and an irradiation time (sec).

The developing solution used for development may be, for example, a developing solution containing water. Examples of water include tap water, natural water, purified water, distilled water, ion-exchange water, pure water, and ultrapure water (such as Milli-Q water). Milli-Q water refers to ultrapure water obtained by a Milli-Q water production apparatus of Merck Millipore (Merck & Co., Inc.). Since impurities are reduced, water may be purified water, distilled water, ion-exchange water, pure water, or ultrapure water. The proportion of water contained in the developing solution may be, for example, 80% by mass or more based on the total amount of the developing solution.

The pH of the developing solution may be 14 or less, 12 or less, 11 or less, 10 or less, or 8 or less, and may be 1 or more, 2 or more, 4 or more, or 6 or more. In a case where the developing solution is neutral or nearly neutral, deterioration of components such as a dicing tape and a dicing ring can be suppressed.

The developing solution may contain a hydrophilic organic solvent. Examples of the hydrophilic organic solvent include alcohols such as methanol, ethanol, 2-propanol, and 1,2-propanediol; and glycol ethers such as ethylene glycol monomethyl ether, propylene glycol monomethyl ether, ethyl cellosolve, propylene glycol monopropyl ether, propylene glycol monoisopropyl ether, butyl cellosolve, ethylene glycol monoisobutyl ether, propylene glycol monobutyl ether, diethylene glycol dimethyl ether, diethylene glycol diethyl ether, and dipropylene glycol monomethyl ether.

The developing solution may contain a pH adjuster. Examples of the pH adjuster include an inorganic acid, an inorganic base, an organic acid, and an organic base. Examples of the inorganic acid include nitric acid, sulfuric acid, hydrochloric acid, phosphoric acid, and boric acid. Examples of the inorganic base include sodium hydroxide, potassium hydroxide, and calcium hydroxide. Examples of the organic acid include formic acid, acetic acid, propionic acid, butyric acid, acrylic acid, benzoic acid, and picolinic acid. Examples of the organic base include primary amine, secondary amine, tertiary amine, tetramethylammonium hydroxide, tetraethylammonium hydroxide, and an imidazole-based compound.

A positive-type photosensitive resin layer which can be developed with a neutral or nearly neutral developing solution containing water can be, for example, a layer containing a polymer having a chemical bond (for example, a disulfide bond) that is cleaved by light irradiation and a hydrophilic group. An example of such a positive-type photosensitive resin layer contains a reaction product (polymer) of a polythiol compound (hereinafter, also referred to as “compound (A)”) having a disulfide bond and a cyclic ether compound (hereinafter, also referred to as “compound (B)”) having a polyether chain as a hydrophilic group and two or more cyclic ether groups, and a photoradical generator. In this case, this photosensitive resin layer has a property of being melted by light irradiation. When the photosensitive resin layer containing a reaction product of the compound (A) and the compound (B) and a photoradical generator is irradiated with light, the photoradical generator cleaves the disulfide bond (—S—S—) in the reaction product of the compound (A) and the compound (B). Thereby, the molecular weight of the reaction product of the compound (A) and the compound (B) is decreased, and the reaction product can become a liquid (liquid state).

Since the resin component produced by decreasing the molecular weight of the reaction product of the compound (A) and the compound (B) has many polyether chains or hydroxyl groups and tends to exhibit hydrophilicity, this resin component dissolves in the developing solution containing water. Therefore, in the case of using such a photosensitive resin layer, the photosensitive resin layer can be removed by development using a developing solution containing water.

The reaction product of the compound (A) and the compound (B) may be specifically a product of curing reaction of the compound (A) and the compound (B). The photosensitive resin layer 30 containing a reaction product of the compound (A) and the compound (B) and a photoradical generator can be formed, for example, by a method containing producing a thermosetting composition containing the compound (A), the compound (B), a curing accelerator, and a photoradical generator, and curing this thermosetting composition by heating. In this case, it can be said that the photosensitive resin layer 30 contains a cured product of the above-described thermosetting composition.

The thermosetting composition containing the compound (A), the compound (B), a curing accelerator, and a photoradical generator can be produced, for example, by mixing the compound (A), the compound (B), a curing accelerator, and a photoradical generator.

The compound (A) is a compound having a disulfide bond (—S—S—) and two or more thiol groups (—SH). The upper limit of the number of thiol groups of the compound (A) may be, for example, 5 or less. The compound (A) may be, for example, a dithiol compound which is a compound having two thiol groups (—SH). The compound (A) may be a high-molecular weight component of a polymer or an oligomer. The compound having two thiol groups (—SH) can be regarded as a compound consisting of two thiol groups and a group (first linking group) connecting these two thiol groups and containing a disulfide bond.

The molecular weight or number average molecular weight of the compound (A) may be, for example, 100 to 10000000, 200 to 3000000, 300 to 1000000, 400 to 10000, or 500 to 5000. Note that, the number average molecular weight is a polystyrene conversion value determined by a gel permeation chromatography (GPC) method using a calibration curve obtained by standard polystyrene.

The compound (A) has one or a plurality of (two or more) disulfide bonds in the molecule. The number of disulfide bonds in the compound (A) may be, for example, 1 to 1000 or 4 to 50.

The compound (A) may be a compound (for example, a polymer or an oligomer) having a linear or branched molecular chain and a terminal group and a disulfide bond in this molecular chain. In this case, the terminal group in the compound (A) may be a thiol group. When the compound (A) is such a compound, there is a tendency that a cured product having excellent photo-meltability is more easily formed. The molecular chain in the compound (A) may contain a disulfide bond and a polyether chain, and may be composed of a disulfide bond and a polyether chain.

The compound (A) may be, for example, a compound (compound (1)) represented by Formula (1): HS—(X—S—S)ₙ₁—X—SH. In the formula, “X” represents a polyether chain. A plurality of X's may be the same as or different from each other. “n1” represents an integer of 1 or more. “n1” may be, for example, 1 or more or 4 or more, and may be 1000 or less. When the compound (A) is the compound represented by Formula (1), the group represented by —(X—S—S)ₙ₁—X— is a first linking group. The compound in which the chain of the compound (1) is extended may be, for example, a Michael adduct of the compound (1) or a thiourethanated product of the compound (1).

The polyether chain as “X” may be, for example, a polyoxyalkylene chain. The polyether chain as “X” may be, for example, a group represented by —X¹—O—X²—O—X³—. X¹ to X³ each independently may be an alkylene group, and may be an alkylene group having 1 to 2 carbon atoms (for example, a methylene group or an ethylene group). Examples of the polyether chain as “X” include CH₂CH₂—O—CH₂—O—CH₂CH₂—.

Examples of commercially available products of the compound (A) include THIOKOL LP series (dithiol having a disulfide bond, manufactured by Toray Fine Chemicals Co., Ltd.). The compound (A) can also be obtained by converting a reactive functional group of a compound having a reactive functional group (for example, a carboxy group or a hydroxy group) at the terminal and a disulfide bond into a thiol group. Examples of the compound having a reactive functional group at the terminal and a disulfide bond include 3,3′-dithiodipropionic acid (manufactured by Tokyo Chemical Industry Co., Ltd.), dithiodiethanol, and cystamine.

The content of the compound (A) in the thermosetting composition may be 15% by mass or more, 25% by mass or more, or 35% by mass or more, and may be 80% by mass or less, 70% by mass or less, or 60% by mass or less, based on the total amount of the thermosetting composition.

The compound (B) is a compound having a polyether chain and two or more cyclic ether groups. When the photosensitive resin layer 30 containing the cured product of the thermosetting composition containing the compound (B) (specifically, the reaction product of the compound (A) and the compound (B)) is irradiated with light, the molecular weight of the reaction product of the compound (A) and the compound (B) is decreased to produce a resin component having a structure derived from the compound (B). Here, since the compound (B) is a compound having a polyether chain and two or more cyclic ether groups, many resin components having many polyether chains or hydroxyl groups (derived from cyclic ether groups) and tending to exhibit hydrophilicity are produced. Therefore, by using such a compound (B), in the step (b) and the step (d), the photosensitive resin layer 30 can be removed by using a developing solution or cleaning liquid containing water. The compound (B) may be a high-molecular weight component of a polymer or an oligomer.

The cyclic ether group of the compound (B) may be a group obtained by removing one hydrogen atom from a cyclic ether compound. Specific examples of the cyclic ether group of the compound (B) include an oxirane group (for example, an oxiranyl group and an epoxy group), an oxetane group (for example, an oxetanyl group), a tetrahydrofuryl group, and a tetrahydropyranyl group. Among these, the cyclic ether group may be an oxirane group from the viewpoint of reactivity and ease of availability. That is, the compound (B) may be an oxirane compound (epoxy compound) having a polyether chain and two or more oxirane groups (for example, oxtranyl groups or epoxy groups). Note that, in the present specification, the cyclic ether group includes a group having a cyclic ether structure (structure containing a cyclic ether group). For example, the cyclic ether group includes a group having an oxirane structure (a structure containing an oxirane group (for example, an oxiranyl group or an epoxy group)) such as a glycidyl group, a glycidyl ether group, or an epoxycyclohexyl group.

The molecular weight or number average molecular weight of the compound (B) may be, for example, 100 to 1000000, 100 to 500000, 100 to 10000, 150 to 5000, or 200 to 2000. Note that, the number average molecular weight is a polystyrene conversion value determined by a gel permeation chromatography (GPC) method using a calibration curve obtained by standard polystyrene.

In a case where the cyclic ether group of the compound (B) is an oxirane group (for example, an oxiranyl group or an epoxy group), the epoxy equivalent of the compound (B) may be 50 to 2000 g/eq, 80 to 1500 g/eq, or 100 to 1000 g/eq.

The compound (B) may be a compound (hereinafter, also referred to as “compound (B1)”) having two cyclic ether groups, and may be a compound (hereinafter, also referred to as “compound (B2)”) having three or more cyclic ether groups. The compound (B1) can be regarded as a compound consisting of two cyclic ether groups and a group (second linking group) connecting these two cyclic ether groups and containing a polyether chain. The compound (B2) may be a compound having one or more cyclic ether groups as a side chain or substituent of the second linking group in the compound (B1). The compound (B) may include the compound (B1) and the compound (B2) because the curing time of the thermosetting composition can be further shortened, and the photo-meltability of the photosensitive resin layer 30 and the solubility in the developing solution or cleaning liquid containing water can be further improved.

The compound (B1) may be a compound (for example, a polymer or an oligomer) having a linear molecular chain and a terminal group and a polyether chain in this molecular chain. In this case, the terminal group in the compound (B1) may be a cyclic ether group. In a case where the compound (B) is the compound (B1), there is a tendency that the resin component produced by light irradiation on the photosensitive resin layer 30 is easily removed by a developing solution or cleaning liquid containing water. The polyether chain as the molecular chain may have a substituent such as a hydroxyl group or an alkyl group which may have a hydroxyl group. The molecular chain in the compound (B1) may contain a polyether chain and may consist of a polyether chain.

The compound (Bl) may be, for example, a compound (compound (2)) represented by Formula (2): Z-(Y)ₙ₂-Z. In the formula, “Y” represents a polyether chain, and “Z” represents a cyclic ether group. A plurality of Z's may be the same as or different from each other. “n2” represents an integer of 1 or more. “n2” may be, for example, 1 or more or 2 or more, and may be 1000 or less. In a case where the compound (B1) is the compound represented by Formula (2), the group represented by -(Y)ₙ₂- is a second linking group.

The polyether chain as “Y” may be, for example, a polyoxyalkylene chain. The polyether chain as “Y” may be, for example, a group represented by —Y¹—O—Y²—O—Y³—. Y¹ to Y³ each independently may be an alkylene group, and may be an alkylene group having 1 to 3 carbon atoms (for example, a methylene group, an ethylene group, or a propylene group). Examples of the polyether chain as “Y” include —CH₂CH₂—O—CH₂—CH₂—O—CH₂CH₂—.

Examples of commercially available products of the compound (B1) include DENACOL EX series (EX-850, EX-851, EX-821, EX-830, EX-832, EX-841, EX-861, and EX-920, manufactured by Nagase ChemteX Corporation).

The compound (B2) may be a compound having one or more cyclic ether groups as a side chain of the second linking group (polyether chain as “Y”) in the compound (B1).

Examples of commercially available products of the compound (B2) include DENACOL EX series (EX-614B, EX-313, EX-512, and EX-521, manufactured by Nagase ChemteX Corporation).

The content of the compound (B) (the total of the compound (B1) and the compound (B2)) in the thermosetting composition may be 15% by mass or more, 25% by mass or more, or 35% by mass or more, and may be 80% by mass or less, 70% by mass or less, or 60% by mass or less, based on the total amount of the thermosetting composition.

The mass ratio (the content (mass) of the compound (B2)/the content (mass) of the compound (B) (the total of the compound (B1) and the compound (B2)) of the content of the compound (B2) with respect to the content of the compound (B) (the total of the compound (B1) and the compound (B2))) in the thermosetting composition may be 0.01 to 0.40. When this mass ratio is 0.01 or more, there is a tendency that the curing time of the thermosetting composition can be further shortened, and when this mass ratio is 0.40 or less, there is a tendency that the photo-meltability of the photosensitive resin layer 30 and the solubility in the developing solution or cleaning liquid containing water of the resin component produced by light irradiation on the photosensitive resin layer 30 can be further improved. This mass ratio may be 0.02 or more or 0.03 or more, and may be 0.35 or less, 0.30 or less, 0.25 or less, 0.20 or less, 0.15 or less, 0.10 or less, or 0.05 or less.

An equivalent ratio of the cyclic ether group of the compound (B) with respect to the thiol group of the compound (A) (the cyclic ether group of the compound (B)/the thiol group of the compound (A)) may be, for example, 0.5 to 2.5. When this equivalent ratio is 0.5 or more, there is a tendency that the solubility in the developing solution or cleaning liquid containing water of the resin component produced by light irradiation on the photosensitive resin layer 30 can be further improved, and when this equivalent ratio is 2.5 or less, there is a tendency that the photo-meltability of the photosensitive resin layer 30 can be further improved. This equivalent ratio may be 0.8 or more, 1.0 or more, 1.2 or more, or 1.5 or more, and may be 2.2 or less or 2.0 or less.

The curing accelerator is a component for promoting a (curing) reaction of the compound (A) and the compound (B), and includes a component (catalyst type curing agent) functioning as a catalyst for the curing reaction. Examples of the curing accelerator include an amine compound, an imidazole derivative, a quaternary ammonium salt, an organometallic salt, and a phosphorus compound.

Examples of the amine compound include dicyandiamide, trimethylamine, triethylamine, tripropylamine, tributylamine, tri-n-octylamine, dimethylethylamine, dimethylpropylamine, dimethylbutylamine, dimethyl-n-octylamine, 1,4-diazabicyclo[2.2.2]octane, 1,8-diazabicyclo[5.4.0]undeca-7-ene, benzyldimethylamine, 4-methyl-N, N-dimethylbenzylamine, 2,4,6-tris(dimethylaminomethyl)phenol, and 4-dimethylaminopyridine.

Examples of the imidazole derivative include 1-(1-cyanomethyl)-2-ethyl-4-methyl-1H-imidazole, 2-ethyl-4-methylimidazole, 2-methylimidazole, 2-phenylimidazole, 1-cyanoethyl-2-phenylimidazole, 2-phenyl-4,5-dihydroxymethylimidazole, 2-phenyl-4-methyl-5-hydroxymethylimidazole, 2,4,5-triphenylimidazole, 1-benzyl-2-imidazole, 1,2-dimethylimidazole, and 1-benzyl-2-phenylimidazole.

Examples of the quaternary ammonium salt include tetramethylammonium chloride, tetraethylammonium chloride, tetrabutylammonium chloride, benzyltrimethylammonium chloride, benzyltriethylammonium chloride, benzyltributylammonium chloride, tetramethylammonium bromide, tetraethylammonium bromide, tetrabutylammonium bromide, benzyltrimethylammonium bromide, benzyltriethylammonium bromide, tetramethylammonium iodide, tetraethylammonium iodide, tetrabutylammonium iodide, and benzyltributylammonium iodide.

Examples of the organometallic salt include organometallic salts such as bis(2,4-pentanedionato)zinc(II), zinc octylate, zinc naphthenate, cobalt naphthenate, copper naphthenate, iron acetylacetone, nickel octylate, and manganese octylate.

Examples of the phosphorus compound include tetraphenyl phosphonium tetra-p-tolyl borate, tetraphenyl phosphonium tetraphenyl borate, triphenylphosphine, tri-p-tolyl phosphine, tris(4-chlorophenyl)phosphine, tris(4-methoxyphenyl)phosphine, tris(2,6-dimethoxyphenyl)phosphine, triphenylphosphine triphenylborane, tetraphenyl phosphonium dicyanamide, and tetraphenyl phosphonium tetra(4-methylphenyl)borate.

The content of the curing accelerator may be 0.01% by mass or more, 0.1% by mass or more, or 0.5% by mass or more, and may be 10% by mass or less, 5% by mass or less, or 2% by mass or less, based on the total amount of the thermosetting composition.

The photoradical generator is a component generating a radical by light irradiation. Examples of the photoradical generator include a hydrogen abstraction type photoradical polymerization initiator generating a radical by extracting hydrogen from another molecule by light irradiation, and an intramolecular cleavage type photoradical polymerization initiator generating two radicals by photocleaving itself by light irradiation. The photoradical generator may be an intramolecular cleavage type photoradical polymerization initiator from the viewpoint of facilitating the (photo-melting) reaction of the photosensitive resin layer 30.

Examples of a hydrogen abstraction type photoradical generator include a hexaarylbisimidazole (HABI) compound, a benzophenone compound, a thioxanthone compound, a fluorenone compound, and an a-diketone compound.

Examples of the HABI compound include 2,2′-bis(o-chlorophenyl)-4,4′,5,5′-tetraphenyl biimidazole (for example, 2,2′-bis(2-chlorophenyl)-4,4′,5,5′-tetraphenyl-1, 2′-biimidazole), 2,2′-bis(o-bromophenyl)-4,4′,5,5′-tetraphenyl biimidazole, 2,2′-bis(o, p-dichlorophenyl)- 4,4′,5,5′-tetraphenyl biimidazole, 2,2-bis(o-chlorophenyl)-4,4′,5,5′-tetra(m-methoxyphenyl)biimidazole, 2,2′-bis(0,0′-dichlorophenyl)-4,4′,5,5′-tetraphenyl biimidazole, 2,2′-bis(o-nitrophenyl)-4,4′,5,5′-tetraphenyl biimidazole, and 2,2′-bis(o-methylphenyl)-4,4′,5,5′-tetraphenyl biimidazole.

Examples of the benzophenone compound include 4,4′-bis(dimethylamino)benzophenone and 4,4′-bis(diethylamino)benzophenone.

Examples of the thioxanthone compound include thioxanthone, 2-isopropylthioxanthone, 2-dodecylthioxanthone, 2-cyclohexylthioxanthone, 2,4-diethylthioxanthone, 2,4-dimethylthioxanthone, 1-phenoxythioxanthone, 1-methoxycarbonylthioxanthone, 2-ethoxycarbonylthioxanthone, 3-(2-methoxyethoxycarbonyl)-thioxanthone, 4-butoxycarbonylthioxanthone, 3-butoxycarbonyl-7-methylthioxanthone, 3,4-di-[2-(2-methoxyethoxy)-ethoxycarbonyl]-thioxanthone, 2-chlorothioxanthone, 1-ethoxycarbonyl-3-ethoxythioxanthone, 1-ethoxycarbonyl-3-chlorothioxanthone, 1-chloro-4-n-propoxythioxanthone, 2-methyl-6-dimethoxymethyl-thioxanthone, 2-methyl-6-(1,1-dimethoxybenzyl)-thioxanthone, 6-ethoxycarbonyl-2-methoxy-thioxanthone, 6-ethoxycarbonyl-2-methylthioxanthone, 1-ethoxycarbonyl-3-(1-methyl-1-morpholinoethyl)-thioxanthone, 2-morpholinomethylthioxanthone, 2-methyl-6-morpholinomethylthioxanthone, and thioxanthone-2-carboxylic acid polyethylene glycol ester.

Examples of the fluorenone compound include 9-fluorenone, 3,4-benzo-9-fluorenone, 2-dimethylamino-9-fluorenone, 2-methoxy-9-fluorenone, 2-chloro-9-fluorenone, 2,7-dichloro-9-fluorenone, 2-bromo-9-fluorenone, 2,7-dibromo-9-fluorenone, 2-nitro-9-fluorenone, and 2-acetoxy-9-fluorenone.

Examples of the α-diketone compound include benzil (a compound also referred to as diphenylethanedione or dibenzoyl).

Examples of an intramolecular cleavage type photoradical generator include a benzil ketal-based photoradical generator, an α-aminoalkyl phenone-based photoradical generator, an α-hydroxyalkyl phenone-based photoradical generator, an α-hydroxy acetophenone-based photoradical generator, and an acylphosphine oxide-based photoradical generator.

Examples of the benzil ketal-based photoradical generator include 2,2-dimethoxy-1,2-diphenylethan-1-one (Omnirad 651).

Examples of the α-aminoalkyl phenone-based photoradical generator include 2-benzyl-2-dimethylamino-1-(4-morpholinophenyl)-butanone-1 (Omnirad 369), 2-methyl-1-[4-(methylthio)phenyl]-2-morpholinopropan-1-one (Omnirad 907), and 2-dimethylamino-2-(4-methyl-benzyl)-1-(4-morpholine-4-yl-phenyl)-butan-1-one (Omnirad 379EG).

Examples of the α-hydroxyalkyl phenone-based photoradical generator include 1-hydroxy-cyclohexyl-phenyl-ketone (Omnirad 184).

Examples of the α-hydroxy acetophenone-based photoradical generator include 2-hydroxy-1-{4-[4-(2-hydroxy-2-methyl-propionyl)-benzyl]-phenyl}-2-methyl-propan-1-one (Omnirad 127) and 2-hydroxy-2-methyl-1-phenyl-propan-1-one (Omnirad 1173).

Examples of the acylphosphine oxide-based photoradical generator include 2,4,6-trimethylbenzoyl-diphenyl-phosphine oxide (Omnirad TPO H) and bis(2,4,6-trimethylbenzoyl)-phenylphosphine oxide (Omnirad 819).

The content of the photoradical generator in the thermosetting composition may be 1% by mass or more, 5% by mass or more, or 10% by mass or more, and may be 30% by mass or less, 20% by mass or less, or 15% by mass or less, based on the total amount of the thermosetting composition.

The thermosetting composition may further contain additional components which are other than the compound (A), the compound (B), the curing accelerator, and the photoradical generator. Examples of the additional components include additives such as a plasticizer, an adhesion-imparting agent such as a tackifier, an antioxidant, a leuco dye, a sensitizer, an adhesion improver such as a coupling agent, a polymerization inhibitor, a light stabilizer, a defoaming agent, a filler, a chain transfer agent, a thixotropy-imparting agent, a flame retardant, a mold-releasing agent, a surfactant, a lubricant, and an antistatic agent. As these additives, known additives can be used. The content of the other components in the thermosetting composition may be 0 to 95% by mass, 0.01 to 50% by mass, or 0.1 to 10% by mass, based on the total amount of the thermosetting composition.

By heating the thermosetting composition described above, the (curing) reaction of the compound (A) and the compound (B) (for example, a compound having a glycidyl ether group as a cyclic ether group) proceeds to produce a cured product of the thermosetting composition. Here, the cured product of the thermosetting composition contains a reaction product of the compound (A) and the compound (B) and a photoradical generator. The reaction product of the compound (A) and the compound (B) may be, for example, a compound (polymer) containing a structure represented by the following formula.

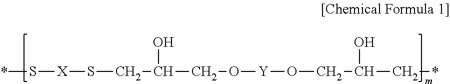

In the formula, “X” represents a first linking group containing a disulfide bond, and “Y” represents a second linking group containing a polyether chain. “m” represents an integer of 1 or more. “m” may be, for example, 50 or more, 100 or more, 500 or more, or 1000 or more. * represents a bonding site.

The heating temperature of the thermosetting composition may be, for example, 0 to 200° C. and may be 30 to 150° C. or 60 to 100° C. The heating time of the thermosetting composition may be, for example, 0.1 to 168 hours, and may be 72 hours or less, 24 hours or less, 12 hours or less, 6 hours or less, 4 hours or less, 3 hours or less, or 2 hours or less.

The aforementioned method of forming the photosensitive resin layer 30 containing the reaction product of the compound (A) and the compound (B) and the photoradical generator may further contain a step of disposing the above-described thermosetting composition on one main surface of the semiconductor wafer 10. In this case, the thermosetting composition is disposed on one main surface of the semiconductor wafer 10, and then heating of the thermosetting composition is performed.

Examples of the method of disposing the thermosetting composition on one main surface of the semiconductor wafer 10 include a method of diluting the thermosetting composition with a solvent to prepare a varnish of the thermosetting composition, and applying the prepared varnish onto one main surface of the semiconductor wafer 10. Examples of the solvent include aromatic hydrocarbons such as toluene, xylene, mesitylene, cumene, and p-cymene; aliphatic hydrocarbons such as hexane and heptane; cyclic alkanes such as methylcyclohexane; cyclic ethers such as tetrahydrofuran and 1,4-dioxane; ketones such as acetone, methyl ethyl ketone, methyl isobutyl ketone, cyclohexanone, and 4-hydroxy-4-methyl-2-pentanone; esters such as methyl acetate, ethyl acetate, butyl acetate, methyl lactate, ethyl lactate, and γ-butyrolactone; carbonic esters such as ethylene carbonate and propylene carbonate; and amides such as N,N-dimethylformamide, N,N-dimethylacetamide, and N-methyl-2-pyrrolidone (NMP). The solid content in the varnish, that is, the total content of components other than the solvent in the varnish may be 10 to 95% by mass, 15 to 70% by mass, or 20 to 50% by mass, based on the total amount of the varnish.

Furthermore, in another embodiment, the aforementioned method of forming the photosensitive resin layer 30 containing the reaction product of the compound (A) and the compound (B) and the photoradical generator may further contain a step of disposing a cured product of the thermosetting composition on one main surface of the semiconductor wafer 10. In this case, heating of the thermosetting composition is performed, and then a cured product of the thermosetting composition is disposed on one main surface of the semiconductor wafer 10. The cured product of the thermosetting composition may be, for example, in a film shape. The film-shaped cured product of the thermosetting composition can be produced, for example, by injecting the aforementioned thermosetting composition into a mold form and heating the thermosetting composition.

The photosensitive resin layer 30 is not limited to the exemplary ones described above, but can be a positive-type or negative-type photosensitive resin layer containing any photosensitive material used for photolithography. For example, the photosensitive resin layer 30 may contain any one of a positive-type or negative-type liquid photoresist, a photosensitive film, a photosensitive solder resist, and a photosensitive polyimide.

In the step (c), the semiconductor wafer 10 is divided along the opening 30a by plasma dicing. Thereby, the semiconductor chip 20 having the first main surface 20a and the second main surface 20b on a side opposite thereto and provided with the photosensitive resin layer 30 on the first main surface 20a is formed.

The plasma dicing means dicing by plasma etching. The conditions of the plasma dicing can be appropriately set according to the type, the thickness, and the like of the semiconductor wafer 10. For the plasma dicing, for example, a dry etching apparatus can be used. For generation of plasma, for example, C₄F₆ gas, C₄F₈ gas, or the like can be used.

The plasma dicing may be performed, for example, by the BOSCH method. In the BOSCH method, the semiconductor wafer 10 can be cut by alternately generating plasma forming a protective film and plasma to be etched. According to the BOSCH method, etching at a high aspect ratio is possible.

In the step (d), the photosensitive resin layer 30 on the semiconductor chip 20 is removed.

The photosensitive resin layer 30 on the semiconductor chip 20 may be removed, for example, by light irradiation and dissolution in a cleaning liquid. In this case, the above-described manufacturing method further contains a step of irradiating the photosensitive resin layer 30 on the semiconductor chip 20 with light.

As the light source used for light irradiation, those described above as the light source used for light irradiation in the step (b) can be used without particular limitation. The light irradiation may be performed collectively on the photosensitive resin layer 30 on each of a plurality of semiconductor chips 20 (for example, all semiconductor chips 20 present on the same dicing tape 50). In this case, examples of the light source used for light irradiation include a mercury lamp (a low-pressure mercury lamp, a medium-pressure mercury lamp, or a high-pressure mercury lamp), a metal halide lamp, and an LED lamp. The light irradiation may be performed directly on the photosensitive resin layer 30, and may be performed through glass or the like. Examples of irradiated light include visible light and ultraviolet light. Light to be irradiated may be, for example, light containing light at a wavelength of 365 nm. The wavelength of light to be irradiated may be, for example, a wavelength of 150 to 550 nm.

The exposure dose of light irradiation may be within the numerical range described above as the exposure dose of light irradiation in the step (b).

As the cleaning liquid, those described above as the developing solution in the step (b) can be used without particular limitation. The pH of the cleaning liquid may be within the numerical range described above as the pH of the developing solution in the step (b).

In another embodiment, the photosensitive resin layer 30 on the semiconductor chip 20 may be removed by ashing. The ashing is performed, for example, by a method containing irradiating the photosensitive resin layer 30 on the semiconductor chip 20 with plasma produced using oxygen gas.

In the step (e), the semiconductor chip 20 and the other semiconductor member 70 are hybrid-bonded such that the first main surface 20a of the semiconductor chip 20 is in contact with the semiconductor member 70. Thereby, a semiconductor device 100 illustrated in FIG. 2(e) is obtained.

The semiconductor chip 20 illustrated in FIG. 2(e) contains a main body part 20A and an electrode 21 and an insulating film 22 provided on one main surface of the main body part 20A. The first main surface 20a of the semiconductor chip 20 is a bonding surface for hybrid bonding composed of the electrode 21 and the insulating film 22. Here, the first main surface 20a of the semiconductor chip 20 corresponds to a surface on which the photosensitive resin layer 30, which has been removed in the step (d), was provided. Furthermore, the semiconductor member 70 contains an electrode 71 and an insulating film 72, and a surface (hereinafter, also referred to as “first main surface of the semiconductor member 70”) 70a, which is in contact with the first main surface 20a of the semiconductor chip 20, of the semiconductor member 70 is a bonding surface composed of the electrode 71 and the insulating film 72. The semiconductor member 70 may be, for example, a semiconductor wafer or a semiconductor chip. The second main surface 20b of the semiconductor chip 20 may also be a bonding surface composed of an electrode and an insulating film. In this case, a plurality of semiconductor chips 20 may be stacked by hybrid bonding.

The electrode 21 and the electrode 71 may each independently contain Cu as a constituent material. The insulating film 22 and the insulating film 72 may each independently contain an inorganic insulator such as SiO₂ or an organic insulator (including a dielectric material) as a constituent material.

As illustrated in FIG. 2(e), the hybrid bonding of the semiconductor chip 20 and the other semiconductor member 70 can be performed by a method containing a step of picking up the semiconductor chip 20 from the dicing tape 50, a step of aligning the semiconductor chip 20 and the semiconductor member 70 such that the first main surface 20a of the semiconductor chip 20 is in contact with the semiconductor member 70, and a step of bonding the semiconductor chip 20 and the semiconductor member 70.

In the step of picking up the semiconductor chip 20 from the dicing tape 50, for example, a needle is pressed from the lower direction of the dicing tape 50, the dicing tape 50 is curved, and the semiconductor chip 20 is picked up from the dicing tape 50 by a suction collet. In the case of an ultraviolet curable dicing tape in which the adhesive strength of the dicing tape 50 is reduced by irradiation with ultraviolet rays, the adhesive strength of the dicing tape 50 may be reduced by irradiation with ultraviolet rays before this pick-up step.

In the step of aligning the semiconductor chip 20 and the semiconductor member 70 such that the first main surface 20a of the semiconductor chip 20 is in contact with the semiconductor member 70, the first main surface 20a of the semiconductor chip 20 and the first main surface 70a of the semiconductor member 70 are disposed such that the electrode 21 and the insulating film 22 face the electrode 71 and the insulating film 72, respectively.

In the step of bonding the semiconductor chip 20 and the semiconductor member 70, the first main surface 20a of the semiconductor chip 20 and the first main surface 70a of the semiconductor member 70 are brought into contact with each other. More specifically, the electrode 21 and the insulating film 22 are brought into contact with the electrode 71 and the insulating film 72, respectively.

In the step of bonding the semiconductor chip 20 and the semiconductor member 70, at least one of heating and pressurization may be performed. The heating temperature may be, for example, 20° C. or higher or 200° C. or higher and may be 500° C. or lower or 400° C. or lower. The pressurization pressure may be, for example, 0.1 MPa or more and may be 1.0 MPa or less.

The above-described manufacturing method may contain a step of activating at least one bonding surface of the first main surface 20a of the semiconductor chip 20 and the first main surface 70a of the semiconductor member 70 before the first main surface 20a of the semiconductor chip 20 and the first main surface 70a of the semiconductor member 70 are brought into contact with each other. In the case of containing the step of activating the bonding surface, the bonding of the semiconductor chip 20 and the semiconductor member 70 becomes easy.

Examples of the method of activating the bonding surface include a method of hydrophilicizing the bonding surface, and a method of removing a non-active substance (such as an oxide film) of the bonding surface. Examples of the method of hydrophilicizing the bonding surface include a method of irradiating the bonding surface with oxygen plasma. Furthermore, examples of the method of removing a non-active substance of the bonding surface include a method of irradiating the bonding surface with ion beams (for example, Ar ion beams) under high vacuum.

The step of activating the bonding surface may be performed, for example, after the step of removing the photosensitive resin layer 30 on the semiconductor chip 20. Furthermore, the step of activating the bonding surface may be performed before the step of picking up the semiconductor chip 20 from the dicing tape 50 in the step of bonding the semiconductor chip 20 and the semiconductor member 70.

### REFERENCE SIGNS LIST

10: semiconductor wafer, 20: semiconductor chip, 20a: first main surface, 20b: second main surface, 20A: main body part, 21: electrode, 22: insulating film, 30: photosensitive resin layer, 30a: opening, 50: dicing tape, 70: semiconductor member, 70a: first main surface, 71: electrode, 72: insulating film, 100: semiconductor device.

1. A manufacturing method of a semiconductor device, the manufacturing method comprising:
a step of forming a photosensitive resin layer on one main surface of a semiconductor wafer;
a step of forming an opening through which the semiconductor wafer is exposed by removing a part of the photosensitive resin layer by light irradiation and development using a developing solution;
a step of dividing the semiconductor wafer along the opening by plasma dicing to form a semiconductor chip having a first main surface and a second main surface on a side opposite thereto and provided with the photosensitive resin layer on the first main surface;
a step of removing the photosensitive resin layer on the semiconductor chip; and
a step of hybrid bonding the semiconductor chip and another semiconductor member such that the first main surface of the semiconductor chip is in contact with the semiconductor member.

2. The manufacturing method according to claim 1, wherein the developing solution is a developing solution comprising water.

3. The manufacturing method according to claim 2, wherein a pH of the developing solution is 11 or less.

4. The manufacturing method according to claim 1, wherein the photosensitive resin layer is a positive-type photosensitive resin layer.

5. The manufacturing method according to claim 4, further comprising a step of irradiating the photosensitive resin layer on the semiconductor chip with light, wherein
the photosensitive resin layer on the semiconductor chip is removed by dissolution in a cleaning liquid.

6. The manufacturing method according to claim 5, wherein the cleaning liquid is a cleaning liquid containing water.

7. The manufacturing method according to claim 6, wherein a pH of the cleaning liquid is 11 or less.

8. The manufacturing method according to claim 4, wherein the developing solution is a developing solution comprising water.

9. The manufacturing method according to claim 8, wherein a pH of the developing solution is 11 or less.

10. The manufacturing method according to claim 8, wherein the photosensitive resin layer comprises a reaction product of a polythiol compound having a disulfide bond and a cyclic ether compound having a polyether chain and two or more cyclic ether groups, and a photoradical generator.
